(19) United States
(12) Patent Application Publication
(10) Pub. No.: US 2021/0097250 A1
(43) Pub. Date: Apr. 1, 2021

(54) FINGERPRINT RECOGNITION SUBSTRATE AND DRIVING METHOD OF DISPLAY DEVICE

(71) Applicants: Hefei BOE Optoelectronics Technology Co., Ltd., Hefei (CN); BOE TECHNOLOGY GROUP CO., LTD., Beijing (CN)

(72) Inventors: Jian TAO, Beijing (CN); Lei ZHANG, Beijing (CN); Hongmin LI, Beijing (CN); Junsheng CHEN, Beijing (CN)

(21) Appl. No.: 16/826,402

(22) Filed: Mar. 23, 2020

(30) Foreign Application Priority Data
Sep. 26, 2019 (CN) 201910915331.0

(51) Int. Cl. G06K 9/00; G09G 3/20; G06F 3/044

(52) U.S. Cl. CPC G06K 9/0002; G09G 2354/00; G06F 3/0446; G09G 3/20

(57) ABSTRACT

The present disclosure provides a fingerprint recognition substrate, including: an electrode driving circuit, a signal line extending in a first direction, and a gate line extending in a second direction, where the electrode driving circuit is connected to the signal line and the gate line; and a functional electrode layer comprising a first electrode connected to the electrode driving circuit and a second electrode extending in the second direction, where a mutual capacitance is formed by the first electrode and the second electrode, and where multiple ones of the first electrode disposed in a same column along the first direction are connected a same one of the signal line through the electrode driving circuit, respectively.

### CROSS-REFERENCE TO RELATED APPLICATION

This application claims priority to Chinese Patent Application No. 201910915331.0, filed on Sep. 26, 2019, the contents of which are incorporated by reference in the entirety herein.

### TECHNICAL FIELD

The present disclosure relates to the field of display technology and, in particular, to a fingerprint recognition substrate and a driving method of a display device.

### BACKGROUND

In the related art, terminals with fingerprint recognition module have been developed in which a fingerprint recognition module is fixed at a specific position of a respective terminal device, thereby allowing the terminal to identify the user by recognizing the fingerprint of the user.

The above information disclosed in the Background section is only used to enhance the understanding of the background of the present disclosure, so it may include information that does not constitute the prior art known to those of ordinary skill in the art.

### SUMMARY

The present disclosure provides a fingerprint recognition substrate and a driving method of a display device.

To achieve various objectives as described herein, the present disclosure adopts the following technical solutions.

According to a first aspect of the present disclosure, a fingerprint recognition substrate is provided, where the fingerprint recognition substrate includes:

a back plate;

an electrode driving circuit layer disposed on a side of the back plate, where the electrode driving circuit layer is disposed with an electrode driving circuit, a signal line extending in a first direction, and a gate line extending in a second direction, where the electrode driving circuit is connected to the signal line and the gate line; and

a functional electrode layer comprising a first electrode connected to the electrode driving circuit and a second electrode extending in the second direction,

where a mutual capacitance is formed by the first electrode and the second electrode; and

where multiple ones of the first electrode disposed in a same column along the first direction are connected a same one of the signal line through the electrode driving circuit, respectively.

In an exemplary embodiment of the present disclosure, the electrode driving circuit includes:

a switching transistor, where a first end of the switching transistor is connected to the first electrode, a second end of the switching transistor is connected to the signal line, and a control end of the switching transistor is connected to the gate line.

In an exemplary embodiment of the present disclosure, the first electrode and the second electrode are disposed in a same layer, and the mutual capacitance is formed by a sidewall of the first electrode and a sidewall of the second electrode.

In an exemplary embodiment of the present disclosure, the second electrode comprises a plurality of second sub-electrodes connected electrically. The mutual capacitance is formed by the side wall of the first electrode and side walls of the plurality of second sub-electrodes.

In an exemplary embodiment of the present disclosure, the second electrode further comprises a first connection section and a second connection section. A first end of each of the second sub-electrodes is electrically connected to the first connection section. A second end of each of the second sub-electrodes is electrically connected to the second connection section.

In an exemplary embodiment of the present disclosure, the mutual capacitance is formed by the side wall of the first electrode and a side wall of one of the second sub-electrodes.

In an exemplary embodiment of the present disclosure, the functional electrode layer includes:

a first electrode layer disposed with the first electrode;

a second electrode layer stacked with the first electrode layer, and disposed with the second electrode; and

a dielectric layer disposed between the first electrode layer and the second electrode layer,

where an orthographic projection of the first electrode on the back plate overlaps partially with an orthographic projection of the second electrode on the back plate.

In an exemplary embodiment of the present disclosure, the functional electrode layer is disposed on a side of the electrode driving circuit layer away from the back plate.

In an exemplary embodiment of the present disclosure, a size of the orthographic projection of the first electrode on the back plate in the first direction and in the second direction is 80 μm-120 μm.

In an exemplary embodiment of the present disclosure, a size of the second electrode in the first direction is 3 mm-5 mm.

According to a second aspect of the present disclosure, a method for driving a display device is provided. The display device includes the fingerprint recognition substrate described above, and the method for driving the display device includes:

in a fingerprint recognition phase, applying a bias voltage signal to the second electrode, and applying a scan signal progressively to the electrode driving circuit through the scan line to connect the first electrode progressively to the signal line, thereby loading a first detection signal to the signal line; and receiving the first detection signal from the signal line; and

in a touch phase, applying a conducting signal to the electrode driving circuit to simultaneously electrically connecting multiple ones of the first electrode disposed in the same column along the first direction to the same one of the signal line through the electrode driving circuit, and progressively applying a driving signal to the second electrode, thereby loading a second detection signal to the signal line; and receiving the second detection signal from the signal lines.

In an exemplary embodiment of the present disclosure, the method further includes short-circuit connecting the signal line with at least one adjacent signal line using a control circuit to form a signal line group comprising at least two signal lines.

In an exemplary embodiment of the present disclosure, applying the bias voltage signal to the second electrode, and applying the scan signal progressively to the electrode driving circuit through the scan line to connect the first electrode progressively to the signal line, includes:

generating, by cascaded shift registers, the scan signal output sequentially, where output ends of the cascaded shift registers are connected to corresponding ones of the scan line to apply the scan signal progressively to the electrode driving circuit.

In an exemplary embodiment of the present disclosure, generating, by the cascaded shift registers, the scan signal output sequentially includes:

applying a high-level signal to an input end of a first-stage shift register, so that a unique high-level output is generated at an output end of the first-stage shift register in one driving cycle, and the high-level output is output as the scan signal to the scan line in a first row; and

inputting the high-level output to an input end of a next-stage shift register to generate the scan signal output sequentially by the cascaded shift registers.

In an exemplary embodiment of the present disclosure, applying the conducting signal to the electrode driving circuit to simultaneously electrically connecting multiple ones of the first electrode disposed in the same column along the first direction to the same one of the signal line through the electrode driving circuit, includes:

generating the conducting signal output simultaneously by cascaded shift registers, where output ends of the cascaded shift registers are connected to corresponding ones of the scan line to simultaneously apply the conducting signal to the gate driving circuit.

In an exemplary embodiment of the present disclosure, generating the conducting signal output simultaneously by cascaded shift registers includes:

applying high-level signals to respective control terminals of the cascaded shift registers, so that output ends of the shift registers output high level output during entire driving cycle, and simultaneously applying the high-level output as the conducting signal to respective gate line.

In an exemplary embodiment of the present disclosure, short-circuit connecting the signal line with at least one adjacent signal line using the control circuit includes:

sending a short circuit signal to the control circuit, such that a predetermined number of signal lines are short circuited to form a plurality of signal line groups.

In an exemplary embodiment of the present disclosure, a total width of the predetermined number of signal lines in the second direction is substantively equal to a width of the second electrode in the first direction.

According to a third aspect of the present disclosure, a method for driving a display device is provided, the display device including the fingerprint recognition substrate described above, where the display device further includes a control circuit, and the control circuit is connected to each of the signal lines. The driving method of the display device includes:

in a fingerprint recognition phase, loading a bias voltage signal to each of the touch electrodes; sequentially loading a scanning signal to each of the gate lines, and, in response to loading the scanning signal to any one of the gate lines, such that the electrode driving circuit is connected to the gate line, making the fingerprint recognition electrode and the signal line electrically connected, thereby loading a first detection signal to the signal line; and receiving the first detection signal from each of the signal lines; and

in a touch phase, sending a short-circuit signal to the control circuit to divide all of the signal lines into a plurality of signal line groups, and any one of the signal line groups including a plurality of the signal lines disposed adjacently and making each of the signal lines in a same signal line group electrically connected each other; loading the scanning signal to each of the gate lines simultaneously to electrically connect each of the fingerprint recognition electrodes to the signal line, thereby loading a second detection signal to the signal line group; receiving the second detection signal from each of the signal line groups; and receiving detection signals from each of the touch electrodes.

### BRIEF DESCRIPTION OF THE DRAWINGS

The above and other features and advantages of the present disclosure will become more apparent by describing example embodiments in detail with reference to the accompanying drawings.

FIG. 1 is a schematic circuit diagram of a fingerprint recognition substrate according to an embodiment of the present disclosure.

FIG. 2 is a schematic structural diagram of an electrode driving circuit layer and a fingerprint recognition electrode of a fingerprint recognition substrate according to an embodiment of the present disclosure.

FIG. 3 is a schematic structural diagram of a functional electrode layer of a fingerprint recognition substrate according to an embodiment of the present disclosure.

FIG. 4 is a schematic structural cross-sectional view of the fingerprint recognition substrate at DD′ in FIG. 3 according to an embodiment of the present disclosure.

FIG. 5 is a schematic diagram of a shift register circuit according to an embodiment of the present disclosure.

FIG. 6 is a timing diagram of a shift register circuit in a fingerprint recognition phase according to an embodiment of the present disclosure.

FIG. 7 is a timing diagram of a shift register circuit in a touch phase according to an embodiment of the present disclosure.

### DETAILED DESCRIPTION

Example embodiments will now be described more fully with reference to the accompanying drawings. However, the example embodiments can be implemented in various forms and should not be construed as limited to the examples set forth herein. Rather, providing these embodiments makes the disclosure more comprehensive and complete, and conveys the concepts of the example embodiments comprehensively to those skilled in the art. The described features, structures, or characteristics may be combined in any suitable manner in one or more embodiments. In the following description, many specific details are provided to give a full understanding of the embodiments of the present disclosure.

In the figures, thicknesses of areas and layers may be exaggerated for clarity. The same reference numerals in the drawings denote the same or similar structures, and thus their detailed description will be omitted.

The reference numerals of the main components in the figure are described as follows:

100, Back Plate; 210, Light-Shielding Layer; 220, Active Layer; 230, Gate Insulating Layer; 240, Gate layer; 241, Gate line; 251, First Passivation Layer; 252, Second Passivation Layer; 253, Shielding Layer; 254, Third Passivation Layer; 260, Source-Drain Material Layer; 261, Signal Line; 262, Signal Line Group; 310, Fingerprint Recognition Electrode; 320, Touch Electrode; 321, Sub-Touch Electrode; 322, First Connection Section; 323, Second Connection Section; 324, Touch Lead; 400, Electrode Driving Circuit; 410, Switching Transistor; 500, Mutual Capacitance; A, First Direction; B, Second Direction; C. Touch Recognition Area.

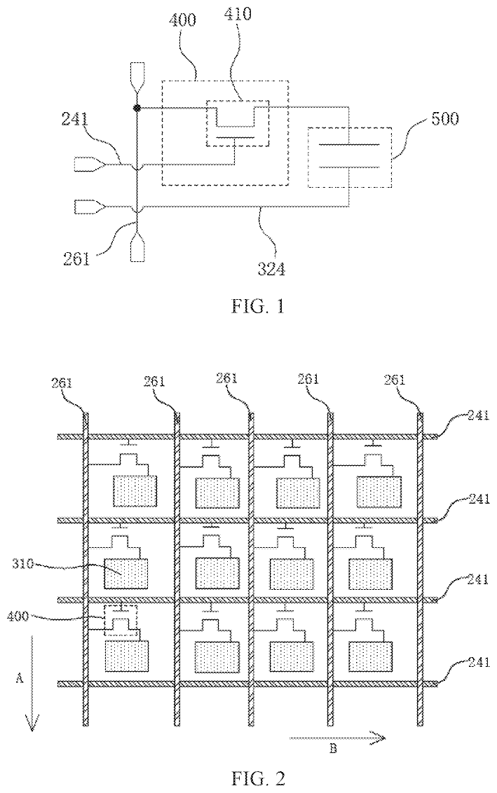

An embodiment of the present disclosure provides a fingerprint recognition substrate. As shown in FIGS. 1 to 4, the fingerprint recognition substrate includes a back plate 100, an electrode driving circuit layer, and a functional electrode layer.

The electrode driving circuit layer is disposed on a side of the back plate 100, and the electrode driving circuit layer is disposed with an electrode driving circuit 400 distributed in an array. A plurality of signal lines 261 extend in a first direction A, and a plurality of gate lines 241 extend in a second direction B. Any one of the signal lines 261 is connected to a plurality of electrode driving circuits 400, any one of the gate lines 241 is connected to the plurality of electrode driving circuits 400, and any one of the electrode driving circuits 400 is connected to the signal line 261 and the gate line 241. The functional electrode layer and the electrode driving circuit layer are disposed on a same side of the back plate 100, and the functional electrode layer is disposed with an fingerprint recognition electrode 310 distributed in an array and a plurality of touch electrodes 320 extending along the second direction B. The fingerprint recognition electrode 310 and the electrode driving circuit 400 are electrically connected in a one-to-one correspondence, and any one of the fingerprint recognition electrodes 310 and the touch electrode 320 form a mutual capacitance 500.

In a fingerprint recognition phase, the touch electrode 320 can be used to provide a bias voltage to the fingerprint recognition electrode 310, so that the mutual capacitance 500 formed between the fingerprint recognition electrode 310 and the touch electrode 320 can be used as a fingerprint recognition sensor, such that the electrode 320 is multiplexed into one electrode of the fingerprint recognition sensor. In this way, in the fingerprint recognition phase, each of the electrode driving circuits 400 can be scanned line by line to obtain a first detection signal of each of the fingerprint recognition electrodes 310 loaded on the signal line 261, thereby realizing the fingerprint recognition function. In a touch phase, each of the electrode driving circuits 400 can be applied simultaneously with a conducting signal, so that each of the fingerprint recognition electrodes 310 is simultaneously connected to the signal line 261. In this way, each of the fingerprint recognition electrodes 310 connected to a same signal line 261 can be electrically connected to each other to form an integral electrode extending along the first direction A. Based on this, by progressively (i.e., line by line) scanning the touch electrodes 320, the mutual capacitance 500 as a touch sensor may be formed between the integral electrode and the touch electrode 320. When a capacitance value of the mutual capacitance 500 is changed by a touch, a second detection signal is generated on the scan line 261, so that coordinates of a touch position in the first direction A can be determined according to the scan position of the touch electrode 320 corresponding to the time of generating the second detection signal. Coordinates of a touch position in the second direction B can be determined according to the second detection signal on the integral electrode. In this way, each of the fingerprint recognition electrodes 310 can be reused as an electrode of a touch sensor for determining the touch position.

The fingerprint recognition substrate of the present disclosure can form a mutual-capacitance fingerprint recognition sensor and a touch sensor by using time-division multiplexing using only two electrodes, thereby realizing time-division multiplexing of the fingerprint recognition electrode and the touch electrode, and further reducing the manufacturing and/or material cost and the thickness of the fingerprint recognition substrate.

In addition, the fingerprint recognition substrate of the present disclosure realizes the time-division multiplexing of the fingerprint recognition electrode and the touch electrode, so a fingerprint recognition range can be not less than a touch range, and fingerprint recognition in the full screen range can be realized.

The fingerprint recognition substrate of the present disclosure can be externally attached to a display panel, for example, through adherence to an OLED (organic electroluminescence) display panel, LCD (liquid crystal) display panel, micro-LED (microdiode) display panel, QLED (quantum dot) display panel, PDP (plasma) display panel, or other type of display panel surface using optical glue or other suitable compound, thereby obtaining a display device with fingerprint recognition and touch control function. The fingerprint recognition substrate described herein has a lower thickness and cost due to the time-division multiplexing of the fingerprint recognition electrode and the touch electrode, so that the display device can also have a lower thickness and cost and, in some embodiments, can achieve full-screen fingerprint recognition.

The components of the fingerprint recognition substrate provided by the embodiments of the present disclosure are described in detail below with reference to the drawings:

The back plate 100 may be a back plate 100 made of an inorganic material or a back plate 100 made of an organic material. For example, in an embodiment of the present disclosure, materials of the back plate 100 may be glass materials such as soda-lime glass, quartz glass, and sapphire glass. In another embodiment of the present disclosure, the materials of the back plate 100 may be polymethyl methacrylate (PMMA), polyvinyl alcohol (PVA), or polyvinyl phenol (PVP), polyether sulfone (PES), polyimide, polyamide, polyacetal, poly carbonate (PC), polyethylene terephthalate (PET), polyethylene naphthalate (PEN) or a combination thereof. In another embodiment of the present disclosure, the back plate 100 may also be a flexible back plate 100. For example, the material of the back plate 100 may be polyimide (PI).

As shown in FIG. 1, the electrode driving circuit 400 is used to control electrical connection or electrical disconnection between the fingerprint recognition electrode 310 and the signal line 261 connected thereto under the control of a control signal loaded on the gate line 241. Optionally, when the gate line 241 loads a scanning signal to the electrode driving circuit 400, the electrode driving circuit 400 may electrically connect the fingerprint recognition electrode 310 to the signal line 261, so that the signal line 261 may generate a corresponding first detection signal based on a state of the fingerprint recognition electrode 310. When a signal loaded on the gate line 241 is not a scanning signal, the electrode driving circuit 400 may be disconnected.

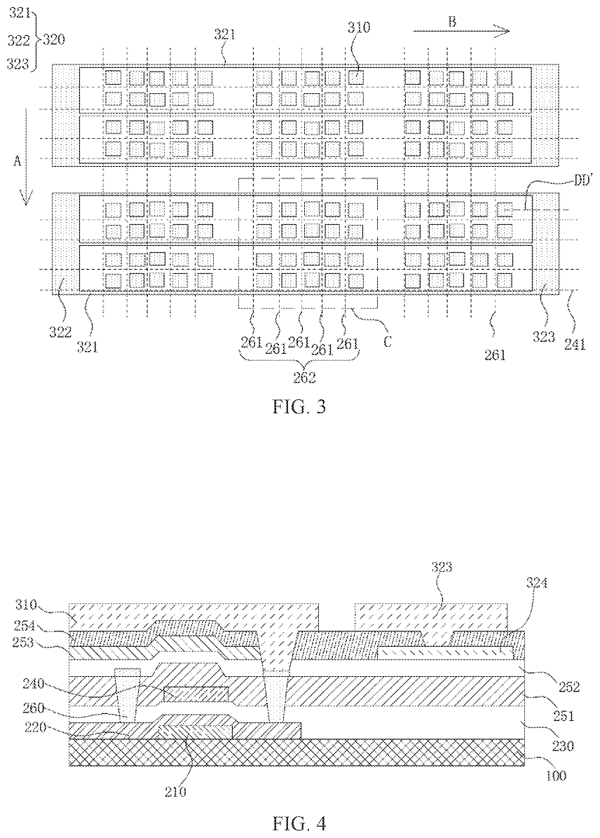

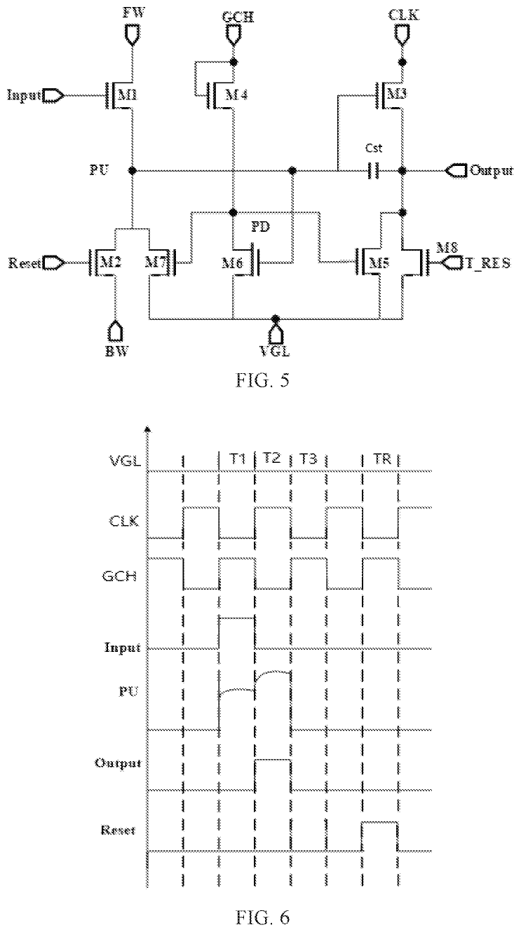

In an embodiment of the present disclosure, as shown in FIG. 1, the electrode driving circuit 400 includes a switching transistor 410, where a first end of the switching transistor 410 is connected to the fingerprint recognition electrode 310, a second end of the switching transistor 410 is connected to the signal line 261, and a control end of the switching transistor 410 is connected to the gate line 241. In this way, as shown in FIG. 2 and FIG. 3, when the gate line 241 is loaded with the scanning signal line by line, a line-by-line scanning of the fingerprint recognition electrode 310 can be realized, thereby realizing the fingerprint recognition. When the scanning signal is simultaneously loaded on the gate line 241 (in this case, the scanning signal may be referred to as conducting signal), all of the fingerprint recognition electrodes 310 can be connected to the signal line 261 simultaneously, so that all of the fingerprint recognition electrodes 310 connected to a same signal line 261 form an integral electrode for touch detection, thereby realizing the touch detection. In this way, the electrode driving circuit 400 can enable the fingerprint recognition substrate to realize time-division multiplexing of a fingerprint recognition function and a touch function.

The switching transistor 410 may be a top-gate transistor or a bottom-gate transistor, which is not particularly limited in this disclosure.

For example, as shown in FIG. 4, the fingerprint recognition substrate may include a back plate 100, a light-shielding layer 210, an active layer 220, a gate insulating layer 230, a gate layer 240, a first passivation layer 251, a source-drain material layer 260, a second passivation layer 252, a shielding layer 253, a third passivation layer 254, and an electrode material layer, which are sequentially stacked.

The light-shielding layer 210 is disposed on a side of the back plate 100. The active layer 220 is disposed on a side of the light-shielding layer 210 away from the back plate 100, and the active layer 220 is disposed with a channel area, a source contact area, and a drain contact area of the switching transistor 410. The gate insulating layer 230 is disposed on a side of the active layer 220 away from the back plate 100. The gate layer 240 is disposed on a side of the gate insulating layer 230 away from the back plate 100. The gate layer 240 is disposed with a gate of the switching transistor 410 and a gate line 241 electrically connected to the gate of the switching transistor 410. The first passivation layer (PVX1) 251 is disposed on a side of the gate layer 240 away from the back plate 100. The source-drain material layer 260 is disposed on a side of the first passivation layer 251 away from the back plate 100. The source-drain material layer 260 is disposed with a source of the switching transistor 410, a drain of the switching transistor 410, and a signal line 261, where the source of the switching transistor 410 is electrically connected to the source contact area of the switching transistor 410 through a metallized via, the drain of the switching transistor 410 is electrically connected to the drain contact area of the switching transistor 410 through the metallized via, and the signal line 261 is electrically connected to the source of the switching transistor 410. The second passivation layer (PVX2) 252 is disposed on a side of the source-drain material layer 260 away from the back plate 100. The shielding layer 253 is disposed on a side of the second passivation layer 252 away from the back plate 100. The third passivation layer (PVX3) 254 is disposed on a side of the shielding layer 253 away from the back plate 100. The electrode material layer is disposed on a side of the third passivation layer 254 away from the back plate 100. The electrode material layer is disposed with a fingerprint recognition electrode 310, and the fingerprint recognition electrode 310 is electrically connected to the drain of the switching transistor 410 through the metallized via.

Optionally, the material of the electrode material layer may be ITO (Indium Tin Oxide).

An extension direction of the signal line 261 is a first direction A, and the extension direction of the gate line 241 is a second direction B. The first direction A and the second direction B are not parallel. Optionally, as shown in FIG. 2, the first direction A and the second direction B are perpendicular to each other, and are both parallel to a plane on which the back plate 100 is located.

In an embodiment of the present disclosure, as shown in FIG. 4, the fingerprint recognition electrode 310 and the touch electrode 320 are disposed on a same surface, and a sidewall of the fingerprint recognition electrode 310 and a sidewall of the touch electrode 320 form a mutual capacitance 500. In this way, the mutual capacitance 500 between the fingerprint recognition electrode 310 and the touch electrode 320 is a MOM capacitor (metal-oxide-metal capacitor, also referred to as a finger capacitor). On one hand, this can reduce a number of layers of the fingerprint recognition substrate, thereby reducing the thickness of fingerprint recognition substrate. On the other hand, the fingerprint recognition electrode 310 and the touch electrode 320 can be formed simultaneously in a same patterning process, which simplifies the preparation of the fingerprint recognition substrate.

For example, as shown in FIG. 4, the touch electrodes 320 and the fingerprint recognition electrodes 310 are both disposed on the electrode material layer, and both of them can be ITO. In other words, the electrode material layer may be formed with the fingerprint recognition electrode 310 and the touch electrode 320 at the same time.

Optionally, the accuracy of fingerprint recognition may be higher than the accuracy of touch so a size of fingerprint recognition electrode 310 needs to be smaller than a size of touch electrode 320. As shown in FIG. 3, in order to make the size of the touch electrode 320 match the size of the fingerprint recognition electrode 310, to avoid excessive touch accuracy, or to avoid insufficient fingerprint recognition accuracy, any one of the touch electrodes 320 may include a plurality of electrically connected sub-touch electrodes 321. A sidewall of any one of the fingerprint recognition electrodes 310 and a sidewall of the sub-touch electrode 321 form the mutual capacitance 500. In this way, a size of the sub-touch electrode 321 can be matched with the size of the fingerprint recognition electrode 310, and the plurality of sub-touch electrodes 321 form one touch electrode 320 to match the touch accuracy.

Optionally, as shown in FIG. 3, any one of the touch electrodes 320 may further include a first connection section 322 and a second connection section 323. A first end of each sub-touch electrode 321 is electrically connected to the first connection section 322. A second end of each of the sub-touch electrodes 321 is electrically connected to the second connection section 323. In this way, each of the sub-touch electrodes 321 is in a strip shape, which facilitates the preparation of the touch electrode 320.

Optionally, any one of the sub-touch electrodes 321 extends along the second direction B.

Optionally, as shown in FIG. 3, any one of the fingerprint recognition electrodes 310 forms the mutual capacitance 500 with only one sub-touch electrode 321. In this way, a capacitance value of each of the mutual capacitances 500 is consistent, thereby ensuring the effects of fingerprint recognition and touch detection.

Optionally, as shown in FIG. 3, two rows of the fingerprint recognition electrodes 310 are disposed between two adjacent sub-touch electrodes 321 in a same touch electrode 320, and the electrode driving circuit 400 corresponding to any row of the fingerprint recognition electrodes 310 is connected to a same gate line 241.

Optionally, as shown in FIG. 4, the fingerprint recognition substrate may further include a touch lead 324, which is disposed outside a touch area of the fingerprint recognition substrate and is electrically connected to the touch electrode 320, so that a driving circuit may receive a detection signal on the touch electrode 320 through the touch lead 324 or loads a bias voltage to the touch electrode 320 through the touch lead 324.

In an embodiment of the present disclosure, as shown in FIG. 4, the touch lead 324 is disposed between the second passivation layer 252 and the third passivation layer 254, and is electrically connected to the touch electrode 320 through the metallization via.

In another embodiment of the present disclosure, the functional electrode layer may include a first electrode layer, a second electrode layer, and a dielectric layer.

The first electrode layer is disposed with a fingerprint recognition electrode 310; the second electrode layer and the first electrode layer are stacked and disposed with a touch electrode 320. A dielectric layer is disposed between the first electrode layer and the second electrode layer. An orthographic projection of the fingerprint recognition electrode 310 on a back plate 100 overlaps partially with an orthographic projection of the touch electrode 320 on the back plate 100.

In this way, the mutual capacitance 500 between the fingerprint recognition electrode 310 and the touch electrode 320 is an MIM capacitor, and an area between the fingerprint recognition electrode 310 and the touch electrode 320 is large, which is beneficial to increase the capacitance of the mutual capacitance 500, thereby improving the accuracy of fingerprint recognition and touch.

A size of the touch electrode 320 may be determined according to the touch accuracy requirement of the fingerprint recognition substrate. The higher the touch accuracy required by the fingerprint recognition substrate, the smaller the size of the touch electrode 320 in the first direction A can be, so as to improve PPI of the touch electrode 320. On the contrary, the lower the touch accuracy required by the fingerprint recognition substrate, the larger the size of the touch electrode 320 in the first direction A can be, so as to reduce the PPI of the touch electrode 320.

Optionally, in order to avoid the problems that the PPI of the touch electrode 320 is too high and the driving is complicated and the touch leads 324 are too many while maintaining a certain touch accuracy, a size of any one of the touch electrodes 320 in the first direction A can be 3 mm-5 mm. In an embodiment of the present disclosure, the size of the touch electrode 320 in the first direction A may be 4 mm, that is, a width of the touch electrode 320 is 4 mm.

In order to ensure the accuracy of fingerprint recognition and cause the fingerprint recognition substrate can effectively match a valley of the fingerprint, the fingerprint recognition electrode 310 may have a large PPI. Optionally, a size of the orthographic projection of the fingerprint recognition electrode 310 on the back plate 100 is 80 μm -120 μm. For example, in an embodiment of the present disclosure, the PPI of the fingerprint recognition electrode 310 is about 280, and a size of a single fingerprint recognition electrode 310 is about 90 μm. In the present embodiment, since the fingerprint recognition electrode 310 generally has a rectangular-like shape, the above-discussed size will be interpreted as a size in the first direction A is 80 μm-120 μm, and a size in the second direction B is also 80 μm -120 μm.

In an embodiment of the present disclosure, each of the signal lines 261 of the fingerprint recognition substrate of the present disclosure may be used to be connected to a control circuit. As shown in FIG. 3, in a touch phase, the control circuit may cause all of the signal lines 261 to be divided into a plurality of signal line groups 262, any one of the signal line groups 262 includes a plurality of signal lines 261 disposed adjacently, and each of the signal lines 261 in a same signal line group 262 are electrically connected to each other. In this way, the plurality of signal line groups 262 in the same signal line group 262 and the fingerprint recognition electrodes 310 connected to the signal lines 261 are electrically connected to each other and serve as one electrode for realizing the touch function. Further, a size of any one of the signal line groups 262 in the second direction B is the same as the size of the touch electrode 320 in the first direction A.

For example, as shown in FIG. 3, in an embodiment of the present disclosure, the size of the touch electrode 320 in the first direction A is 4 mm. The size of any one of the signal line groups 262 in the second direction B is 4 mm. In this way, in the touch phase, the fingerprint recognition substrate can form a touch recognition area C arranged in an array, where any of the touch recognition areas C is an intersection area of the touch electrode 320 and the signal line group 262, and a range of any one of the touch recognition areas C is 4 m×4 mm.

The fingerprint recognition substrate of the present disclosure can be used to be electrically connected to a gate driving circuit. The gate driving circuit can provide scanning signals to each of the gate lines 241 line by line during the fingerprint recognition phase, and simultaneously provide scanning signals to each of the gate lines 241 during the touch phase, so that the fingerprint recognition substrate can realize time-division multiplexing of the fingerprint recognition function and the touch function.

Optionally, the gate driving circuit may include a plurality of cascaded shift register circuits, and an output end of the shift register circuit may be connected to an input end of the gate line 241 in a one-to-one correspondence. For example, in an embodiment of the present disclosure, the switching transistor 410 of the electrode driving circuit 400 is turned on under a control of a high level, that is, when the scanning signal loaded on the gate line 241 is at the high level, the switching transistor 410 is turned on. The shift register circuit may include a first transistor to an eighth transistor, as well as a storage capacitor.

An input end of a first transistor M1 is connected to a high level end FW, an output end of the first transistor M1 is connected to a pull-up node PU, and a control end of the first transistor M1 is connected to a first input end Input. The first input end Input of current stage is used to connect an output end Output of the shift register circuit of previous stage. The first transistor M1 is used to input a high level signal on the high level end FW to the pull-up node PU under the control of the first input end Input. The high level end FW remains a high level.

An input end of a second transistor M2 is connected to a low level end BW, an output end of the second transistor M2 is connected to the pull-up node PU, and a control end of the second transistor M2 is connected to a reset signal end Reset. The second transistor M2 is used to input a low level signal of the low level end BW to the pull-up node PU under the control of a reset signal on the reset signal end Reset. The low level end BW remains a low level.

An input end of a third transistor M3 is connected to a first clock signal end CLK, an output end of the third transistor M3 is connected to the output end Output of the shift register circuit, and a control end of the third transistor M3 is connected to the pull-up node PU. It can be understood that the output end Output of the shift register circuit of current stage can be connected to the gate line 241 and the first input end Input of the shift register circuit of next stage; the third transistor M3 is used to load a voltage on the first clock signal end CLK to the output end Output of the shift register circuit under the control of the pull-up node PU.

A first end of a storage capacitor Cst is connected to the pull-up node PU, and a second end of the storage capacitor Cst is connected to the output end Output of the shift register circuit. The storage capacitor Cst is used to maintain the voltage of the pull-up node PU.

An input end and a control end of a fourth transistor M4 are connected to a second clock signal end GCH, and an output end of the fourth transistor M4 is connected to the pull-down node PD. The fourth transistor M4 is configured to load a voltage on the second clock signal end GCH to the pull-down node PD under the control of the voltage on the second clock signal end GCH. Levels on the first clock signal end CLK and the second clock signal end GCH are inverted levels, that is, when the first clock signal end CLK is loaded with a high level, the second clock signal end GCH is loaded with a low level, and when the first clock signal end CLK is loaded with a low level, the second clock signal end GCH is loaded with a high level.

An input end of a fifth transistor M5 is connected to a second input end VGL, an output end of the fifth transistor M5 is connected to the output end Output of the shift register circuit, and a control end of the fifth transistor M5 is connected to the pull-down node PD. The fifth transistor M5 is used to load a voltage of the second input end VGL to the output end Output of the shift register circuit under the control of the pull-down node PD.

An input end of a sixth transistor M6 is connected to a second input end VGL, an output end of the sixth transistor M6 is connected to the pull-down node PD, and a control end of the sixth transistor M6 is connected to the pull-up node PU. The sixth transistor M6 is used to input a voltage signal of the second input end VGL to the pull-down node PD under the control of the pull-up node PU. Furthermore, the fourth transistor M4 and the sixth transistor M6 have appropriate sizes. When the second clock signal end GCH provides a high level signal to the pull-down node PD through the fourth transistor M4, and when the second input end VGL inputs a low level signal to the pull-down node PD through the sixth transistor M6, a voltage on the pull-down node PD is low level.

An input end of a seventh transistor M7 is connected to the second input end VGL, an output end of the seventh transistor M7 is connected to the pull-up node PU, and a control end of the seventh transistor M7 is connected to the pull-down node PD. The seventh transistor M7 is used to input the voltage signal of the second input end VGL to the pull-up node PU under the control of the pull-down node PD.

An input end of an eighth transistor M8 is connected to the second input end VGL, an output end of the eighth transistor M8 is connected to the output end Output of the shift register circuit, and a control end of the eighth transistor M8 is connected to a third input end T_RES. The eighth transistor M8 is used to input the voltage signal of the second input end VGL to the output end Output of the shift register circuit under the control of the third input end T_RES. The third input end T_RES of the shift register circuit of current stage is connected to an output end Output of the shift register circuit of next stage, that is, the output end Output of the shift register circuit of current stage is connected to the third input end T_RES of the shift register circuit of previous stage.

FIG. 6 is a timing diagram of a shift register circuit during a fingerprint recognition phase, where a low level signal is loaded on the second input end VGL.

At a first moment T1, the first input end Input is loaded with a high level signal, that is, the output end Output of the shift register circuit of previous stage is a high level signal. The reset signal end Reset is loaded with a low level signal, then the first transistor M1 is turned on and the second transistor M2 is turned off, so that a high level signal of the high level end FW is loaded to the pull-up node PU. When a low level signal is loaded on the first clock signal end CLK, the third transistor M3 is turned on under the control of the pull-up node PU, and loads the low level signal on the first clock signal end CLK to the output end Output of the shift register circuit, so that the output end Output of the shift register circuit of current stage outputs a low level signal. A high level signal on the second clock signal end GCH causes the fourth transistor M4 to be turned on; the sixth transistor M6 is turned on under the control of the pull-up node PU. A low level signal is loaded on the second input end VGL, so that the pull-down node PD is at a low level under the control of the fourth transistor M4 and the sixth transistor M6. The fifth transistor M5 and the seventh transistor M7 are turned off under the control of the pull-down node PD. A low level signal output from the output end Output of the shift register circuit of next stage can control the eighth transistor M8 to be turned off, so as to maintain the output end Output of the current-stage shift register circuit to output a low level signal.

At a second moment T2, a high level signal is loaded on the first clock signal end CLK, and the third transistor M3 is turned on under the control of the pull-up node PU, and loads the high level signal on the first clock signal end CLK to the output end Output of the shift register circuit, so that the output end Output of the shift register circuit of current stage outputs a high level signal. A high level signal output from the output end Output of the shift register circuit of current stage is loaded to the third input end T_RES of the shift register circuit of previous stage, so that causes the output end Output of the shift register circuit of previous stage outputs a low voltage, that is, the first input end Input of the shift register circuit of current stage is a low level signal, and the first transistor M1 is turned off. When the reset signal end Reset is loaded with a low level signal, the second transistor M2 is turned off. The pull-up node PU is kept at a high level under the control of the storage capacitor Cst. When the second clock signal end GCH is loaded with a low level signal, the fourth transistor M4 is turned off. Under the control of the pull-up node PU, the sixth transistor M6 is turned on, so that the pull-down node PD remains at a low level, and the fifth transistor M5 and the seventh transistor M7 are turned off. The low level signal output from the output end Output of the shift register circuit of next stage can control the eighth transistor M8 to be turned off to maintain the output end Output of the shift register circuit of current stage to output a high level signal.

At a third moment T3, a low level signal output from the output end Output of the shift register circuit of previous stage is loaded to the first input end Input of the shift register circuit of current stage, so that the first transistor M1 remains off. The reset signal end Reset is loaded with a low level signal, so that the second transistor M2 remains off. The second clock signal end GCH is loaded with a high level signal, so that the fourth transistor M4 is turned on, and thus the voltage of the pull down node PD is a high level. Under the control of the pull-down node PD, the seventh transistor M7 is turned on, so that a low level signal loaded on the second input end VGL is loaded to the pull-up node PU, and the voltage of the pull-up node PU is low level. Under the control of the pull-up node PU, the third transistor M3 is turned off and the sixth transistor M6 is turned off. Under the control of the pull-down node PD, the fifth transistor M5 is turned on. A high level signal output from the output end Output of the shift register circuit of next stage is input to the third input end T_RES of the shift register circuit of current stage, so that the eighth transistor M8 is turned on. In this way, a low level signal of the second input end VGL can be input to the output end Output of the shift register circuit of current stage through the fifth transistor M5 and the eighth transistor M8, so that the shift register circuit of current stage outputs a low level signal.

At a reset timing TR, the first input end Input is loaded with a low level signal, so that the first transistor M1 is turned off; the reset signal end Reset is loaded with a high level reset signal, so that the second transistor M2 is turned on, and then a low level signal of the low level end BW is loaded to the pull-up node PU, so that the pull-up node PU is reset to a low level.

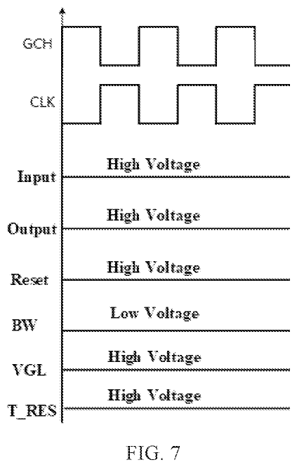

FIG. 7 is a timing diagram of the shift register circuit in a touch phase. According to FIG. 7, in the touch phase, the second input end VGL is loaded with a high level signal, and the reset signal end Reset is loaded with a high level signal. In this way, when the second clock signal end GCH is loaded with a high level signal, the transistor M5 is turned on so that the output end Output of the shift register circuit outputs a high level signal. When the second clock signal end GCH is loaded with a low level signal, under the control of the storage capacitor Cst, the output end Output of the shift register circuit can continue to output a high level signal. In this way, each of the shift register circuits can simultaneously output a high level signal.

An embodiment of the present disclosure further provides a method for driving a display device, having any one of the fingerprint recognition substrates described in the above-mentioned embodiment of the fingerprint recognition substrate. The method for driving the display device may include:

in a fingerprint recognition phase, loading a bias voltage signal on each of the touch electrodes 320; sequentially loading a scanning signal to each of the gate lines 241, and in response to loading the scanning signal to any one of the gate lines 241, the electrode driving circuit 400 connected to the gate line 241, making the fingerprint recognition electrode 310 and the signal line 261 electrically connected, thereby loading a first detection signal to the signal line 261; receiving the first detection signal from each of the signal lines 261. In this way, by scanning each of the fingerprint recognition electrodes 310 line by line, the first detection signal of each of the fingerprint recognition electrodes 310 loaded on the signal line 261 can be obtained; by analyzing each of the first detection signals, the fingerprint recognition can be realized;

in a touch phase, simultaneously loading the scanning signal to each of the gate lines 241 to electrically connect each of the fingerprint recognition electrodes 310 to the signal line 261 and meanwhile progressively applying touch driving signal to the touch electrode 320, thereby loading a second detection signal to the signal line 261; receiving the second detection signal from each of the signal lines 261. In this way, by turning on each of the electrode driving circuits 400 simultaneously, a second detection signal commonly loaded on the signal line 261 by each of the fingerprint recognition electrodes 310 connected to a same signal line 261 can be obtained, and by analyzing the second detection signal on the signal lines 261, it can be determined whether a touch occurs at a position corresponding to the signal line 261, thereby realizing a touch function.

An embodiment of the present disclosure further provides another method for driving a display device, the display device having any one of the fingerprint recognition substrates described in the above-mentioned embodiment of the fingerprint recognition substrate. The display device may further include a control circuit, and the control circuit is connected to each of the signal lines 261. The method for driving the display device may include:

in a fingerprint recognition phase, loading a bias voltage signal to each of the touch electrodes 320; sequentially loading a scanning signal to each of the gate lines 241, and in response to loading the scanning signal to any one of the gate lines 241, the electrode driving circuit 400 connected to the gate line 241 making the fingerprint recognition electrode 310 and the signal line 261 electrically connected, thereby loading a first detection signal to the signal line 261; receiving the first detection signal from each of the signal lines 261; in this way, by scanning each of the fingerprint recognition electrodes 310 line by line, the first detection signal of each of the fingerprint recognition electrodes 310 loaded on the signal line 261 can be obtained; by analyzing each of the first detection signals, the fingerprint recognition can be realized;

in a touch phase, sending a short-circuit signal to the control circuit, to divide all of the signal lines 261 into a plurality of signal line groups 262, and any one of the signal line groups 262 including a plurality of the signal lines 261 disposed adjacently and making each of the signal lines 261 in a same signal line group 262 electrically connected each other; loading the scanning signal to each of the gate lines 241 simultaneously to electrically connect each of the fingerprint recognition electrodes 310 to the signal line 261 and meanwhile progressively applying touch driving signal to the touch electrode 320, thereby loading a second detection signal to the signal line group 262; receiving the second detection signal from each of the signal line groups 262.

In this way, the control circuit can short-circuit each of the signal lines 261 in the same signal line group 262, thereby making each of the fingerprint recognition electrodes 310 in the signal line group 262 to connected to each other; in this way, the control circuit may receive a second detection signal that all of the fingerprint recognition electrodes 310 in the same signal line group 262 are commonly loaded on the signal line group 262. By analyzing the second detection signal on the signal line groups 262, it can be determined whether a touch occurs at a position corresponding to the signal line group 262, thereby realizing a touch function.

According to the fingerprint recognition substrate and the method for driving the display device of the present disclosure, the fingerprint recognition substrate is disposed with a fingerprint recognition electrode and a touch electrode, where, in a fingerprint recognition phase, the touch electrode can be reused as one electrode of a fingerprint recognition sensor; in a touch phase, the fingerprint recognition electrode can be reused as one electrode of a touch sensor. As such, the driving method of the fingerprint recognition substrate and the display device of the present disclosure can realize time-division multiplexing of the fingerprint recognition electrode and the touch electrode, thereby reducing thickness and cost of the fingerprint recognition substrate.

It should be noted that although the steps of the method in the present disclosure are described in a specific order in the drawings, this does not require or imply that the steps must be performed in the specific order, or all steps shown must be performed to achieve desired results. In addition or alternatively, certain steps may be omitted, multiple steps may be combined into one step for execution, and/or one step may be split into multiple steps for execution, etc., shall all be considered as part of the present disclosure.

It should be understood that the present disclosure does not limit its application to the detailed structure and arrangement of the components proposed in this specification. The disclosure is capable of other embodiments and of being practiced and carried out in various ways. The aforementioned variations and modifications fall within the scope of the present disclosure. It should be understood that the disclosure disclosed and defined by this specification extends to all alternative combinations of two or more separate features mentioned or apparent in the text and/or drawings. All of these different combinations constitute various alternative aspects of the present disclosure. The embodiments described in this specification illustrate the best modes known for implementing the disclosure and will enable others skilled in the art to utilize the disclosure.

What is claimed is:

1. A fingerprint recognition substrate, comprising:
a back plate;
an electrode driving circuit layer disposed on a side of the back plate, wherein the electrode driving circuit layer is disposed with an electrode driving circuit, a signal line extending in a first direction, and a gate line extending in a second direction, the electrode driving circuit being connected to the signal line and the gate line; and
a functional electrode layer comprising a first electrode connected to the electrode driving circuit and a second electrode extending in the second direction;
wherein a mutual capacitance is formed by the first electrode and the second electrode; and
wherein multiple ones of the first electrode disposed in a same column along the first direction are connected a same one of the signal line through the electrode driving circuit, respectively.

2. The fingerprint recognition substrate according to claim 1, wherein the electrode driving circuit comprises:
a switching transistor, wherein a first end of the switching transistor is connected to the first electrode, a second end of the switching transistor is connected to the signal line, and a control end of the switching transistor is connected to the gate line.

3. The fingerprint recognition substrate according to claim 1, wherein the first electrode and the second electrode are disposed in a same layer, and the mutual capacitance is formed by a sidewall of the first electrode and a sidewall of the second electrode.

4. The fingerprint recognition substrate according to claim 3, wherein the second electrode comprises a plurality of second sub-electrodes connected electrically, and the mutual capacitance is formed by the side wall of the first electrode and side walls of the plurality of second sub-electrodes.

5. The fingerprint recognition substrate according to claim 4, wherein the second electrode further comprises a first connection section and a second connection section; and a first end of each of the second sub-electrodes is electrically connected to the first connection section;
a second end of each of the second sub-electrodes is electrically connected to the second connection section.

6. The fingerprint recognition substrate according to claim 4, wherein the mutual capacitance is formed by the side wall of the first electrode and a side wall of one of the second sub-electrodes.

7. The fingerprint recognition substrate according to claim 1, wherein the functional electrode layer comprises:
a first electrode layer disposed with the first electrode;
a second electrode layer stacked with the first electrode layer, and disposed with the second electrode; and
a dielectric layer disposed between the first electrode layer and the second electrode layer;
wherein an orthographic projection of the first electrode on the back plate overlaps partially with an orthographic projection of the second electrode on the back plate.

8. The fingerprint recognition substrate according to claim 1, wherein the functional electrode layer is disposed on a side of the electrode driving circuit layer away from the back plate.

9. The fingerprint recognition substrate according to claim 1, wherein a size of the orthographic projection of the first electrode on the back plate in the first direction and in the second direction is 80 μm-120 μm.

10. The fingerprint recognition substrate according to claim 1, wherein a size of the second electrode in the first direction is 3 mm-5 mm.

11. A method for driving a display device, comprising:
providing a fingerprint recognition substrate that comprises:
a back plate;
an electrode driving circuit layer disposed on a side of the back plate, wherein the electrode driving circuit layer is disposed with an electrode driving circuit, a signal line extending in a first direction, and a gate line extending in a second direction, the electrode driving circuit being connected to the signal line and the gate line; and
a functional electrode layer comprising a first electrode connected to the electrode driving circuit and a second electrode extending in the second direction;
wherein a mutual capacitance is formed by the first electrode and the second electrode; and
wherein multiple ones of the first electrode disposed in a same column along the first direction are connected a same one of the signal line through the electrode driving circuit, respectively.
in a fingerprint recognition phase, applying a bias voltage signal to the second electrode, and applying a scan signal progressively to the electrode driving circuit through the scan line to connect the first electrode progressively to the signal line, thereby loading a first detection signal to the signal line; and receiving the first detection signal from the signal line;
in a touch phase, applying a conducting signal to the electrode driving circuit to simultaneously electrically connecting multiple ones of the first electrode disposed in the same column along the first direction to the same one of the signal line through the electrode driving circuit, and progressively applying a driving signal to the second electrode, thereby loading a second detection signal to the signal line; and
receiving the second detection signal from the signal lines.

12. The method according to claim 11, further comprising short-circuit connecting the signal line with at least one adjacent signal line using a control circuit to form a signal line group comprising at least two signal lines.

13. The method according to claim 11, wherein applying the bias voltage signal to the second electrode, and applying the scan signal progressively to the electrode driving circuit through the scan line to connect the first electrode progressively to the signal line, comprises:
generating, by cascaded shift registers, the scan signal output sequentially, wherein output ends of the cascaded shift registers are connected to corresponding ones of the scan line, to apply the scan signal progressively to the electrode driving circuit.

14. The method according to claim 13, wherein generating, by the cascaded shift registers, the scan signal output sequentially comprises:
applying a high-level signal to an input end of a first-stage shift register, so that a unique high-level output is generated at an output end of the first-stage shift register in one driving cycle, and the high-level output is output as the scan signal to the scan line in a first row; and
inputting the high-level output to an input end of a next-stage shift register, to generate the scan signal output sequentially by the cascaded shift registers.

15. The method according to claim 11, wherein applying the conducting signal to the electrode driving circuit to simultaneously electrically connecting multiple ones of the first electrode disposed in the same column along the first direction to the same one of the signal line through the electrode driving circuit comprises:
generating the conducting signal output simultaneously by cascaded shift registers, output ends of the cascaded shift registers are connected to corresponding ones of the scan line, to simultaneously apply the conducting signal to the gate driving circuit.

16. The method according to claim 15, wherein generating the conducting signal output simultaneously by cascaded shift registers comprises:
applying high-level signals to respective control terminals of the cascaded shift registers, so that output ends of the shift registers output high level output during entire driving cycle, and simultaneously applying the high-level output as the conducting signal to respective gate line.

17. The method according to claim 12, wherein the short-circuit connecting the signal line with at least one adjacent signal line using the control circuit comprises:
sending a short circuit signal to the control circuit, such that a predetermined number of signal lines are short circuited to form a plurality of signal line groups.

18. The method according to claim 17, wherein a total width of the predetermined number of signal lines in the second direction is substantively equal to a width of the second electrode in the first direction.
